(19) United States
(12) Patent Application Publication
(10) Pub. No.: US 2025/0366326 A1
(43) Pub. Date: Nov. 27, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventor: HYUNEOK SHIN, Yongin-si (KR)

(21) Appl. No.: 19/040,007

(22) Filed: Jan. 29, 2025

(30) Foreign Application Priority Data
May 21, 2024 (KR) 10-2024-0065732

(51) Int. Cl. H10K 59/131; H10K 59/12; H10K 59/121

(52) U.S. Cl. CPC H10K 59/131; H10K 59/1201; H10K 59/1213

(57) ABSTRACT

A display device includes: a substrate including a first pixel area and a second pixel area spaced apart from the first pixel area in a first direction, a first transistor disposed on the substrate, a first bridge electrode disposed in the first pixel area on the first transistor and electrically connected to the first transistor, a second bridge electrode disposed on the first bridge electrode, and a first electrode disposed on the second bridge electrode.

This application claims priority to Korean Patent Application No. 10-2024-0065732, filed on May 21, 2024, and all the benefits accruing therefrom under 35 U.S.C. § 119, the content of which in its entirety is herein incorporated by reference.

### BACKGROUND

### 1. Technical Field

Embodiments relate to a display device, a method of manufacturing the display device, and an electronic device including the display device. More particularly, embodiments relate to a display device providing visual information, a method of manufacturing the display device, and an electronic device including the display device.

### 2. Description of the Related Art

A display device is a device that displays an image for providing visual information to a user. Among display devices, an organic light emitting diode display device has recently attracted attention.

The display device may include a light emitting element. The light emitting element may include an anode electrode, a light-emitting layer disposed on the anode electrode, and a common electrode disposed on the light-emitting layer. The anode electrode may be separated for each pixel area.

### SUMMARY

Embodiments provide a display device with improved quality.

Embodiments provide a method of manufacturing the display device.

Embodiments provide an electronic device including the display device.

A display device according to an embodiment includes a substrate including a first pixel area and a second pixel area spaced apart from the first pixel area in a first direction, a first transistor disposed on the substrate, a first bridge electrode disposed in the first pixel area on the first transistor and electrically connected to the first transistor, a second bridge electrode disposed on the first bridge electrode, and a first electrode disposed on the second bridge electrode. A width of the second bridge electrode in the first direction is greater than a width of the first bridge electrode in the first direction.

In an embodiment, the display device may further include a second transistor disposed on the substrate and spaced apart from the first transistor in a plan view, a third bridge electrode disposed in the second pixel area on the second transistor and electrically connected to the second transistor, a fourth bridge electrode disposed on the third bridge electrode, and a second electrode disposed on the fourth bridge electrode, where, a width of the fourth bridge electrode in the first direction may be greater than a width of the third bridge electrode in the first direction.

In an embodiment, the first electrode and the second electrode may be separated from each other.

In an embodiment, the first bridge electrode may have a trapezoidal shape in a cross-sectional view.

In an embodiment, the display device may further include a protecting insulating layer covering a side surface of the first bridge electrode.

In an embodiment, the display device may further include a side insulating layer covering at least a portion of each of an upper surface of the first electrode and a side surface of the first electrode.

In an embodiment, the display device may further include a light-emitting layer, where, the light-emitting layer may cover at least a portion of the side insulating layer.

In an embodiment, the light-emitting layer may include a first functional layer disposed on the first electrode and spaced apart from the second pixel area in a plan view, an organic layer disposed on the first functional layer, and a second functional layer disposed on the organic layer.

In an embodiment, the first electrode may cover a side surface of the second bridge electrode.

In an embodiment, a portion of the first bridge electrode and a portion of the second bridge electrode may be spaced apart from each other to define an undercut area.

In an embodiment, the first electrode may include silver (Ag).

In an embodiment, the first electrode may further include indium tin oxide (“ITO”).

In an embodiment, the display device may further include a connecting electrode disposed on the first transistor, where, the first transistor and the first bridge electrode may be electrically connected through the connecting electrode.

A method of manufacturing a display device according to an embodiment includes: forming a transistor on a substrate, forming a first preliminary bridge electrode electrically connected to the transistor on the transistor, forming a second bridge electrode on the first preliminary bridge electrode, forming a first bridge electrode by removing at least a portion of a side surface of the first preliminary bridge electrode, forming a protecting insulating layer covering a side surface of the first bridge electrode, and forming a pixel electrode on the second bridge electrode.

In an embodiment, the forming of the first bridge electrode may include forming a photoresist layer on the second bridge electrode and removing the at least a portion of the side surface of the first preliminary bridge electrode through an etching process.

In an embodiment, the forming of the protecting insulating layer may include forming a preliminary protecting insulating layer covering the first bridge electrode and the second bridge electrode and removing at least a portion of the preliminary protecting insulating layer through an anisotropic dry etching process.

In an embodiment, the forming of the pixel electrode may include forming a portion of the pixel electrode through thermal evaporation.

In an embodiment, the portion of the pixel electrode may include silver (Ag).

In an embodiment, the method may further include forming a side insulating layer covering at least a portion of each of an upper surface of the pixel electrode and a side surface of the pixel electrode.

An electronic device according to an embodiment includes a substrate including a first pixel area and a second pixel area spaced apart from the first pixel area in a first direction, a first transistor disposed on the substrate, a first bridge electrode disposed in the first pixel area on the first transistor and electrically connected to the first transistor, a second bridge electrode disposed on the first bridge electrode, a first electrode disposed on the second bridge electrode, and a memory where data information is stored. A width of the second bridge electrode in the first direction is greater than a width of the first bridge electrode in the first direction.

A display device according to an embodiment may include a substrate including a first pixel area and a second pixel area spaced apart from the first pixel area in a first direction, a first transistor disposed on the substrate, a first bridge electrode disposed in the first pixel area on the first transistor and electrically connected to the first transistor, a second bridge electrode disposed on the first bridge electrode, and a first electrode disposed on the second bridge electrode. A width of the second bridge electrode in the first direction may be greater than a width of the first bridge electrode in the first direct. A portion of the first bridge electrode and a portion of the second bridge electrode may be spaced apart from each other to define an undercut area.

Accordingly, an etching process for forming the first electrode may be omitted. Therefore, a mask for forming the first electrode may not be separately required. In addition, the display device may further include a protecting insulating layer

covering a side surface of the first bridge electrode. Accordingly, when the first electrode is deposited, a short circuit (i.e., direct contact) between the first electrode and the first bridge electrode may be prevented. In addition, the protecting insulating layer may be formed by an anisotropic dry etching process. Accordingly, a mask for forming the protecting insulating layer may not be separately required.

In addition, the display device may further include a side insulating layer covering at least a portion of each of an upper surface of the first electrode and a side surface of the first electrode. Accordingly, leakage current may be prevented from flowing between the first electrode (or pixel electrode) and a common electrode. In addition, a current may be effectively prevented from flowing to an adjacent pixel area through the light-emitting layer.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a cross-sectional view of the display device of FIG. 1 taken along line I-I.

FIG. 3 is an enlarged cross-sectional view of the area A of FIG. 2.

FIGS. 4, 5, 6, 7, 8, 9, 10, 11, 12, 13, 14, 15, 16, 17, and 18 are cross-sectional views illustrating a method of manufacturing the display device of FIG. 2.

FIG. 19 is a block diagram illustrating an electronic device according to embodiments.

FIG. 20 is a schematic diagram of an electronic device according to various embodiments.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “1-1”, “1-2”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, display devices in accordance with embodiments will be described in more detail with reference to the accompanying drawings. The same reference numerals are used for the same components in the drawings, and redundant descriptions of the same components will be omitted.

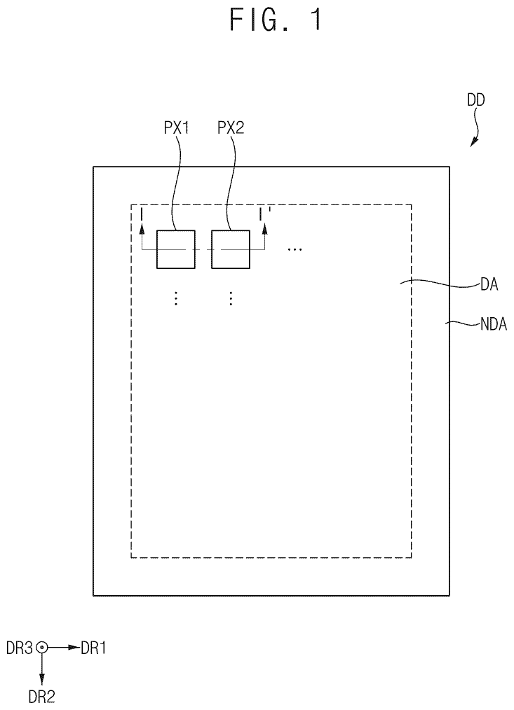

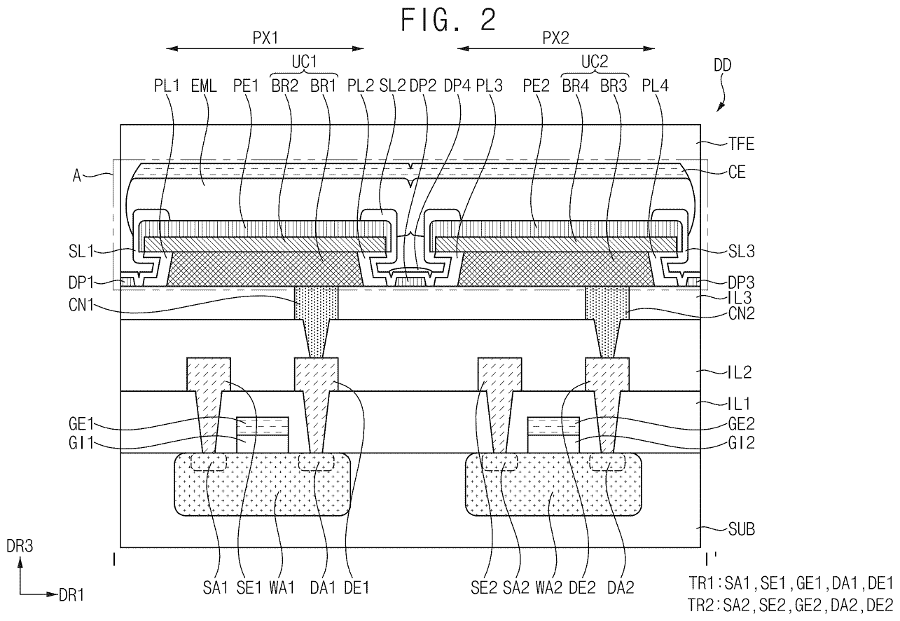

FIG. 1 is a plan view illustrating a display device according to an embodiment. As used herein, the “plan view” is a view in a thickness direction (i.e., third direction DR3) of the display device (specifically, a substrate SUB, See FIG. 2).

Referring to FIG. 1, a display device DD according to an embodiment may include a display area DA and a non-display area NDA.

The display area DA may be an area that generates light or adjusts transmittance of light provided from an external light source to display an image. A plurality of pixel areas may be disposed in the display area DA. For example, a first pixel area PX1 and a second pixel area PX2 may be disposed in the display area DA. Each of the plurality of pixel areas may emit light. For example, each of the first pixel area PX1 and the second pixel area PX2 may emit light.

The plurality of pixel areas may be disposed over an entire display area DA. Accordingly, the display area DA may display an image. In an embodiment, the plurality of pixel areas may be repeatedly arranged along a first direction DR1 and a second direction DR2 crossing the first direction DR1. For example, the second pixel area PX2 may be spaced apart from the first pixel area PX1 in the first direction DR1.

The non-display area NDA may surround at least a portion of the display area DA. A driver may be disposed in the non-display area NDA. The driver may provide a signal or a voltage to the plurality of pixel areas. For example, the driver may include a data driver, a gate driver, and/or the like. The non-display area NDA may not display an image.

In an embodiment, the first direction DR1 and the second direction DR2 crossing the first direction DR1 may be defined. For example, the second direction DR2 may be perpendicular to the first direction DR1. However, this disclosure is not limited thereto, and the second direction DR2 may form an acute angle or an obtuse angle with the first direction DR1 in another embodiment. In addition, a third direction DR3 crossing a plane formed by the first direction DR1 and the second direction DR2 may be defined. For example, the third direction DR3 may be perpendicular to the plane formed by the first direction DR1 and the second directions DR2. However, this disclosure is not limited thereto, and the third direction DR3 may form an acute angle or an obtuse angle with the plane formed by the first direction DR1 and the second direction DR2 in another embodiment.

FIG. 2 is a cross-sectional view of the display device of FIG. 1 taken along line I-I.

Referring to FIGS. 1 and 2, the display device DD according to an embodiment may include a substrate SUB, a first transistor TR1, a second transistor TR2, a first insulating layer IL1, a first gate insulating layer GI1, a second gate insulating layer GI2, a second insulating layer IL2, a first connecting electrode CN1, a second connecting electrode CN2, a third insulating layer IL3, a first undercut structure UC1, a second undercut structure UC2, a first protecting insulating layer PL1, a second protecting insulating layer PL2, a third protecting insulating layer PL3, a fourth protecting insulating layer PL4, a first side insulating layer SL1, a second side insulating layer SL2, a third side insulating layer SL3, a first pixel electrode PE1, a second pixel electrode PE2, a light-emitting layer EML, a common electrode CE, a first dummy layer DP1, a second dummy layer DP2, a third dummy layer DP3, a fourth dummy layer DP4, and an encapsulation layer TFE.

The first transistor TR1 may include a first contact area SA1, a first contact electrode SE1, a first gate electrode GE1, a second contact area DA1, and a second contact electrode DE1. The second transistor TR2 may include a third contact area SA2, a third contact electrode SE2, a second gate electrode GE2, a fourth contact area DA2, and a fourth contact electrode DE2. The first undercut structure UC1 may include a first bridge electrode BR1 and a second bridge electrode BR2. The second undercut structure UC2 may include a third bridge electrode BR3 and a fourth bridge electrode BR4.

As the display device DD includes the first pixel area PX1 and the second pixel area PX2, the substrate SUB may also include the first pixel area PX1 and the second pixel area PX2. The substrate SUB may form a base of the display device DD.

In an embodiment, the substrate SUB may be a silicon substrate. For example, the substrate SUB may be a p-type silicon substrate or an n-type silicon substrate. In this case, p may mean a hole, and n may mean electron. The substrate SUB may include a first well area WA1 and a second well area WA2. The first well area WA1 may be a p-well or an n-well depending on a type of the first transistor TR1 and a type of the substrate SUB. In addition, the second well area WA2 may be a p-well or an n-well depending on a type of the second transistor TR2 and a type of the substrate SUB.

The substrate SUB may include the first contact area SA1 and the second contact area DA1. For example, the first contact area SA1 and the second contact area DA1 may be an n-source area and an n-drain area, respectively. However, this disclosure is not limited thereto, and the first contact area SA1 and the second contact area DA1 may be a p-source area and a p-drain area, respectively in another embodiment.

The substrate SUB may further include the third contact area SA2 and the fourth contact area DA2. For example, the third contact area SA2 and the fourth contact area DA2 may be an n-source area and an n-drain area, respectively. However, this disclosure is not limited thereto, and the third contact area SA2 and the fourth contact area DA2 may be a p-source area and a p-drain area, respectively in another embodiment.

In another embodiment, the substrate SUB may be formed of a transparent resin substrate. Example of the transparent resin substrate may include a polyimide substrate. In this case, the polyimide substrate may include a first organic layer, a first barrier layer, a second organic layer, and/or the like. Optionally, the substrate SUB may include a quartz substrate (e.g. a synthetic quartz substrate, a fluorine-doped quartz substrate), a calcium fluoride substrate, a soda lime glass substrate, a non-alkali glass substrate, or the like. These materials may be used alone or in combination with each other. In this case, the display device DD may include a first active pattern disposed in at least a portion of the first pixel area PX1 and a second active pattern disposed in at least a portion of the second pixel area PX2 on the substrate SUB.

The first gate insulating layer GI1 and the second gate insulating layer GI2 may be disposed on the substrate SUB. The first gate insulating layer GI1 may at least partially overlap the first well area WA1 in a plan view. In addition, the second gate insulating layer GI2 may at least partially overlap the second well area WA2 in a plan view.

Each of the first gate insulating layer GI1 and the second gate insulating layer GI2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first gate electrode GE1 may be disposed on the first gate insulating layer GI1. For example, the first gate electrode GE1 may overlap the first gate insulating layer GI1 in a plan view. The second gate electrode GE2 may be disposed on the second gate insulating layer GI2. For example, the second gate electrode GE2 may overlap the second gate insulating layer GI2 in a plan view.

Each of the first gate electrode GE1 and the second gate electrode GE2 may include a metal, an alloy, a metal nitride, a conductive metal oxide, a transparent conductive material, or the like.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

The first insulating layer IL1 may be disposed on the substrate SUB. The first insulating layer IL1 may sufficiently cover the first gate electrode GE1 and the second gate electrode GE2.

The first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first contact electrode SE1, the second contact electrode DE1, the third contact electrode SE2 and the fourth contact electrode DE2 may be disposed on the first insulating layer IL1. The first contact electrode SE1 may be connected to the first contact area SA1 through a first contact hole defining through the first insulating layer IL1. In addition, the second contact electrode DE1 may be connected to the second contact area DA1 through a second contact hole defining through the first insulating layer IL1. In addition, the third contact electrode SE2 may be connected to the third contact area SA2 through a third contact hole defining through the first insulating layer IL1. In addition, the fourth contact electrode DE2 may be connected to the fourth contact area DA2 through a fourth contact hole defining through the first insulating layer IL1.

Each of the first contact electrode SE1, the second contact electrode DE1, the third contact electrode SE2, and the fourth contact electrode DE2 may include a metal, an alloy metal nitride, a conductive metal oxide, a transparent conductive material, or the like. These may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

That is, the first transistor TR1 and the second transistor TR2 may be disposed on the substrate SUB. The second transistor TR2 may be spaced apart from the first transistor TR1 in a plan view. For example, the second transistor TR2 may be spaced apart from the first transistor TR1 in the first direction DR1. For example, the first transistor TR1 may be disposed in at least a portion of the first pixel area PX1, and the second transistor TR2 may be disposed in at least a portion of the second pixel area PX2.

The second insulating layer IL2 may be disposed on the first insulating layer IL1. The second insulating layer IL2 may sufficiently cover the first contact electrode SE1, the second contact electrode DE1, the third contact electrode SE2 and the fourth contact electrode DE2.

The second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first connecting electrode CN1 and the second connecting electrode CN2 may be disposed on the second insulating layer IL2. The first connecting electrode CN1 may be connected to the second contact electrode DE1 through a fifth contact hole defining through the second insulating layer IL2. In addition, the second connecting electrode CN2 may be connected to the fourth contact electrode DE2 through a sixth contact hole defining through the second insulating layer IL2.

Each of the first connecting electrode CN1 and the second connecting electrode CN2 may include a metal, an alloy metal nitride, a conductive metal oxide, a transparent conductive material, or the like. These may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

The third insulating layer IL3 may be disposed on the second insulating layer IL2. The third insulating layer IL3 may cover at least a portion of each of the first connecting electrode CN1 and the second connecting electrode CN2. In an embodiment, an upper surface of the first connecting electrode CN1 and an upper surface of the third insulating layer IL3 may be positioned at substantially the same level. In this case, the first connecting electrode CN1 may directly contact the first bridge electrode BR1 to be described later. That is, even if the third insulating layer IL3 does not define a contact hole, the first bridge electrode BR1 may contact the first connecting electrode CN1. That is, even if a process of forming a contact hole in the third insulating layer IL3 is omitted, the first bridge electrode BR1 may contact the first connecting electrode CN1.

In addition, an upper surface of the second connection electrode CN2 and the upper surface of the third insulating layer IL3 may be positioned at substantially the same level. In this case, the second connecting electrode CN2 may directly contact the third bridge electrode BR3 to be described later. That is, even if the third insulating layer IL3 does not define a contact hole, the third bridge electrode BR3 may contact the second connecting electrode CN2. That is, even if a process of forming a contact hole in the third insulating layer IL3 is omitted, the third bridge electrode BR3 may contact the second connecting electrode CN2.

However, this disclosure n is not limited thereto, and in another embodiment, the upper surface of the first connecting electrode CN1 and the upper surface of the third insulating layer IL3 may be positioned at different levels. For example, the upper surface of the third insulating layer IL3 may be positioned at a higher level than the upper surface of the first connecting electrode CN1. In this case, the third insulating layer IL3 may define a contact hole, and the first bridge electrode BR1 and the first connecting electrode CN1 may be electrically connected to each other through the contact hole.

In addition, the upper surface of the second connection electrode CN2 and the upper surface of the third insulating layer IL3 may be positioned at different levels. For example, the upper surface of the third insulating layer IL3 may be positioned at a higher level than the upper surface of the second connecting electrode CN2. In this case, the third insulating layer IL3 may define a contact hole, and the third bridge electrode BR3 and the second connecting electrode CN2 may be electrically connected to each other through the contact hole.

In an embodiment, the third insulating layer IL3 may include an organic material. For example, the third insulating layer IL3 may include phenolic resin, acrylic resin, polyimide resin, polyamide resin, siloxane resin, epoxy resin, or the like. These materials may be used alone or in combination with each other. However, this disclosure is not limited thereto, and in another embodiment, the third insulating layer IL3 may include inorganic materials such as silicon oxide and silicon nitride. These materials may be used alone or in combination with each other.

The first bridge electrode BR1 and the third bridge electrode BR3 may be disposed on the third insulating layer IL3. For example, the first bridge electrode BR1 may be disposed on the first transistor TR1. The first bridge electrode BR1 may be disposed in the first pixel area PX1. The first bridge electrode BR1 may be electrically connected to the first transistor TR1. For example, the first bridge electrode BR1 may be electrically connected to the first transistor TR1 through the first connecting electrode CN1.

In addition, the third bridge electrode BR3 may be disposed on the second transistor TR2. The third bridge electrode BR3 may be disposed in the second pixel area PX2. The third bridge electrode BR3 may be electrically connected to the second transistor TR2. For example, the third bridge electrode BR3 may be electrically connected to the second transistor TR2 through the second connecting electrode CN2.

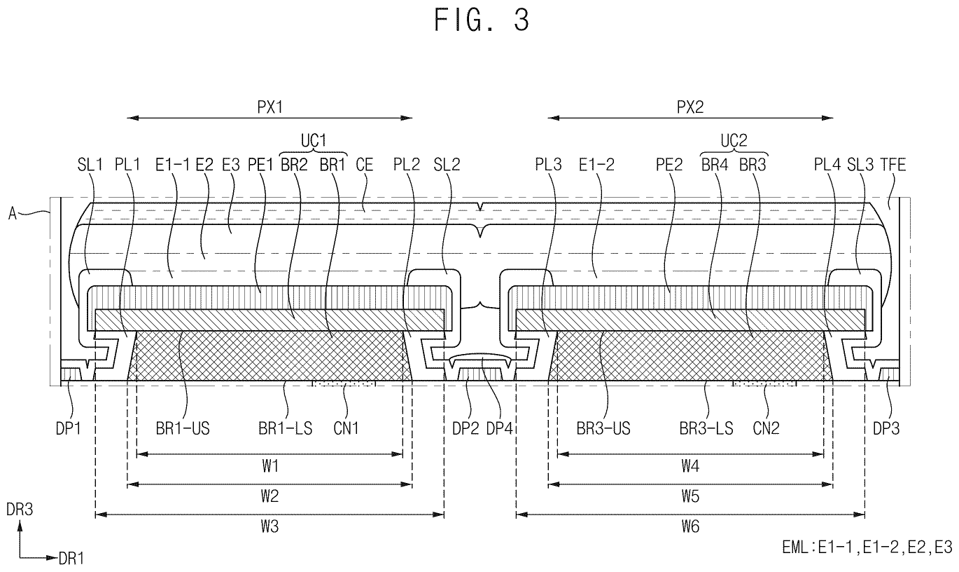

In an embodiment, each of the first bridge electrode BR1 and the third bridge electrode BR3 may have a trapezoidal shape in a cross-sectional view. For example, a side surface of the first bridge electrode BR1 connecting an upper surface (e.g., an upper surface BR1-US of FIG. 3) of the first bridge electrode BR1 and a lower surface (e.g., a lower surface BR1-LS of FIG. 3) of the first bridge electrode BR1 may have a tapered inclined surface. In addition, a side surface of the third bridge electrode BR3 connecting an upper surface (e.g., an upper surface BR3-US of FIG. 3) of the third bridge electrode BR3 and a lower surface (e.g., a lower surface BR3-LS of FIG. 3) of the third bridge electrode BR3 may have a tapered inclined surface.

For example, each of the first bridge electrode BR1 and the third bridge electrode BR3 may include a metal, an alloy metal nitride, a conductive metal oxide, a transparent conductive material, or the like. These may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

The second bridge electrode BR2 may be disposed on the first bridge electrode BR1. The second bridge electrode BR2 may be disposed in the first pixel area PX1. In addition, the fourth bridge electrode BR4 may be disposed on the third bridge electrode BR3. The fourth bridge electrode BR4 may be disposed in the second pixel area PX2.

For example, each of the second bridge electrode BR2 and the fourth bridge electrode BR4 may include a metal, an alloy metal nitride, a conductive metal oxide, a transparent conductive material, or the like. These may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other. In an embodiment, materials included in the second bridge electrode BR2 may be different from materials included in the first bridge electrode BR1.

The first protecting insulating layer PL1 may cover a side surface of the first bridge electrode BR1. For example, the first bridge electrode BR1 may include a first side surface facing the second bridge electrode BR2 and a second side surface opposite to the first side surface in a cross-sectional view, and the first protecting insulating layer PL1 may cover the second side surface of the first bridge electrode BR1. In an embodiment, the first protecting insulating layer PL1 may further cover at least a portion of a lower surface of the second bridge electrode BR2. For example, the first protecting insulating layer PL1 may further cover a portion of the lower surface of the second bridge electrode BR2 protruding from the first bridge electrode BR1 in a direction opposite to the first direction DR1.

The second protecting insulating layer PL2 may cover a side surface of the first bridge electrode BR1. For example, the second protecting insulating layer PL2 may cover the first side surface of the first bridge electrode BR1. In an embodiment, the second protecting insulating layer PL2 may further cover at least a portion of a lower surface of the second bridge electrode BR2. For example, the second protecting insulating layer PL2 may further cover a portion of the lower surface of the second bridge electrode BR2 protruding from the first bridge electrode BR1 in the first direction DR1.

The third protecting insulating layer PL3 may cover a side surface of the third bridge electrode BR3. For example, the third bridge electrode BR3 may include a first side surface facing the first bridge electrode BR1 and a second side surface opposite to the first side surface in a cross-sectional view, and the third protecting insulating layer PL3 may cover the first side surface of the third bridge electrode BR3. In an embodiment, the third protecting insulating layer PL3 may further cover at least a portion of a lower surface of the fourth bridge electrode BR4. For example, the third protecting insulating layer PL3 may further cover a portion of the upper surface of the fourth bridge electrode BR4 protruding from the third bridge electrode BR3 in a direction opposite to the first direction DR1.

The fourth protecting insulating layer PL4 may cover a side surface of the third bridge electrode BR3. For example, the fourth protecting insulating layer PL4 may cover the second side surface of the third bridge electrode BR3. In an embodiment, the fourth protecting insulating layer PL4 may further cover at least a portion of a lower surface of the fourth bridge electrode BR4. For example, the fourth protecting insulating layer PLA may further cover a portion of the lower surface of the fourth bridge electrode BR4 protruding from the third bridge electrode BR3 in the first direction DR1.

The first protecting insulating layer PL1 and the second protecting insulating layer PL2 may prevent a short circuit between the first pixel electrode PE1 and the first bridge electrode BR1 when the first pixel electrode PE1 to be described later is deposited on the second bridge electrode BR2. For example, the first protecting insulating layer PL1 and the second protecting insulating layer PL2 may prevent a short circuit between metal materials used for the first pixel electrode PE1 and the first bridge electrode BR1.

The third protecting insulating layer PL3 and the fourth protecting insulating layer PL4 may prevent a short circuit between the second pixel electrode PE2 and the third bridge electrode BR3 when a second pixel electrode PE2 to be described later is deposited on the fourth bridge electrode BR4. For example, the third protecting insulating layer PL3 and the fourth protecting insulating layer PL4 may prevent a short circuit between metal materials used for the second pixel electrode PE2 and the third bridge electrode BR3.

For example, each of the first protecting insulating layer PL1, the second protecting insulating layer PL2, the third protecting insulating layer PL3, and the fourth protecting insulating layer PL4 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first pixel electrode PE1 may be disposed on the second bridge electrode BR2. The first pixel electrode PE1 may be disposed in the first pixel area PX1. The first pixel electrode PE1 may cover an upper surface of the second bridge electrode BR2. In an embodiment, the first pixel electrode PE1 may further cover a side surface of the second bridge electrode BR2.

For example, the first pixel electrode PE1 may include a metal, an alloy, a conductive metal oxide, a transparent conductive material, or the like. These materials may be used alone or in combination with each other. In an embodiment, the first pixel electrode PE1 may include silver (“Ag”). In an embodiment, the first pixel electrode PE1 may further include indium tin oxide (“ITO”).

The first pixel electrode PE1 may include a plurality of layers. In an embodiment, the first pixel electrode PE1 may include a first layer and a second layer disposed on the first layer. For example, the first layer of the first pixel electrode PE1 may include silver (“Ag”), and the second layer of the first pixel electrode PE1 may include indium tin oxide (“ITO”), but this disclosure is not limited thereto.

In another embodiment, the first pixel electrode PE1 may include a first layer, a second layer disposed on the first layer, and a third layer disposed on the second layer. For example, the first layer of the first pixel electrode PE1 may include indium tin oxide (“ITO”), the second layer of the first pixel electrode PE1 may include silver (“Ag”), and the third layer of the first pixel electrode PE1 may include indium tin oxide (“ITO”), but this disclosure is not limited thereto. In an embodiment, materials included in the second bridge electrode BR2 may be different from materials included in a layer of the first pixel electrode PE1 directly connected to the second bridge electrode BR2.

The first pixel electrode PE1 may operate as an anode. For example, a first light emitting element may include the first pixel electrode PE1, a portion of the light-emitting layer EML, and a portion of the common electrode CE, and the first pixel electrode PE1 may operate as an anode of the first light emitting element. For example, the first pixel electrode PE1 may be referred to as a “first electrode”.

The second pixel electrode PE2 may be disposed on the fourth bridge electrode BR4. The second pixel electrode PE2 may be disposed in the second pixel area PX2. The second pixel electrode PE2 may cover an upper surface of the fourth bridge electrode BR4. In an embodiment, the second pixel electrode PE2 may further cover a side surface of the fourth bridge electrode BR4.

For example, the second pixel electrode PE2 may include a metal, an alloy, a conductive metal oxide, a transparent conductive material, or the like. These materials may be used alone or in combination with each other. In an embodiment, the second pixel electrode PE2 may include silver (“Ag”). In an embodiment, the second pixel electrode PE2 may further include indium tin oxide (“ITO”).

The second pixel electrode PE2 may include a plurality of layers. In an embodiment, the second pixel electrode PE2 may include a first layer and a second layer disposed on the first layer. For example, the first layer of the second pixel electrode PE2 may include silver (“Ag”), and the second layer of the second pixel electrode PE2 may include indium tin oxide (“ITO”), but this disclosure is not limited thereto.

In another embodiment, the second pixel electrode PE2 may include a first layer, a second layer disposed on the first layer, and a third layer disposed on the second layer. For example, the first layer of the second pixel electrode PE2 may include indium tin oxide (“ITO”), the second layer of the second pixel electrode PE2 may include silver (“Ag”), and the third layer of the second pixel electrode PE2 may include indium tin oxide (“ITO”), but this disclosure is not limited thereto.

The second pixel electrode PE2 may operate as an anode. For example, a second light emitting element may include the second pixel electrode PE2, a portion of the light-emitting layer EML, and a portion of the common electrode CE, and the second pixel electrode PE2 may operate as an anode of the second light emitting element. For example, the second pixel electrode PE2 may be referred to as a “second electrode”.

The first dummy layer DP1 may be disposed on the third insulating layer IL3. For example, the first dummy layer DP1 may be spaced apart from the first pixel area PX1 in a direction opposite to the first direction DR1. The first dummy layer DP1 may be formed as the first pixel electrode PE1 is separated by the first undercut structure UC1. That is, the first dummy layer DP1 and the first pixel electrode PE1 may be formed through same process. In an embodiment, the first dummy layer DP1 may be omitted.

The second dummy layer DP2 may be disposed on the third insulating layer IL3. For example, the second dummy layer DP2 may be disposed between the first pixel area PX1 and the second pixel area PX2. The second dummy layer DP2 may be formed as the first pixel electrode PE1 and/or the second pixel electrode PE2 are separated by the first undercut structure UC1 and/or the second undercut structure UC2. That is, the second dummy layer DP2 may be formed through same process as the first pixel electrode PE1 and/or the second pixel electrode PE2. In an embodiment, the second dummy layer DP2 may be omitted.

The third dummy layer DP3 may be disposed on the third insulating layer IL3. For example, the third dummy layer DP3 may be spaced apart from the second pixel area PX2 in the first direction DR1. The third dummy layer DP3 may be formed as the second pixel electrode PE2 is separated by the second undercut structure UC2. That is, the third dummy layer DP3 and the second pixel electrode PE2 may be formed through same process. In an embodiment, the third dummy layer DP3 may be omitted.

The first side insulating layer SL1, the second side insulating layer SL2, and the third side insulating layer SL3 may be disposed on the third insulating layer IL3. The first side insulating layer SL1 may cover at least a portion of an upper surface of the first pixel electrode PE1. For example, the first side insulating layer SL1 may cover a side portion of the upper surface of the first pixel electrode PE1. In an embodiment, the first side insulating layer SL1 may cover at least a portion of a side surface of the first pixel electrode PE1. For example, the first side insulating layer SL1 may cover the entirety of the side surface of the first pixel electrode PE1. In an embodiment, the first side insulating layer SL1 may cover at least a portion of the first protecting insulating layer PL1. For example, the first side insulating layer SL1 may cover the entirety of the first protecting insulating layer PL1. In an embodiment, the first side insulating layer SL1 may cover at least a portion of the first dummy layer DP1. For example, the first side insulating layer SL1 may cover the entirety of the first dummy layer DP1.

The second side insulating layer SL2 may cover at least a portion of the upper surface of the first pixel electrode PE1. For example, the second side insulating layer SL2 may cover a side portion of the upper surface of the first pixel electrode PE1. In an embodiment, the second side insulating layer SL2 may cover at least a portion of the side surface of the first pixel electrode PE1. For example, the second side insulating layer SL2 may cover the entirety of a side surface of the first pixel electrode PE1 facing the second pixel electrode PE2. In an embodiment, the second side insulating layer SL2 may cover at least a portion of the second protecting insulating layer PL2. For example, the second side insulating layer SL2 may cover the entirety of the second protecting insulating layer PL2. In an embodiment, the second side insulating layer SL2 may cover at least a portion of the second dummy layer DP2. For example, the second side insulating layer SL2 may cover the entirety of the second dummy layer DP2. In an embodiment, the second side insulating layer SL2 may cover at least a portion of an upper surface of the second pixel electrode PE2. For example, the second side insulating layer SL2 may cover a side portion of the upper surface of the second pixel electrode PE2. In an embodiment, the second side insulating layer SL2 may cover at least a portion of a side surface of the second pixel electrode PE2. For example, the second side insulating layer SL2 may cover the entirety of a side surface of the second pixel electrode PE2 facing the first pixel electrode PE1. In an embodiment, the second side insulating layer SL2 may cover at least a portion of the third protecting insulating layer PL3. For example, the second side insulating layer SL2 may cover the entirety of the third protecting insulating layer PL3.

The third side insulating layer SL3 may cover at least a portion of the upper surface of the second pixel electrode PE2. For example, the third side insulating layer SL3 may cover a side portion of the upper surface of the second pixel electrode PE2. In an embodiment, the third side insulating layer SL3 may cover at least a portion of the side surface of the second pixel electrode PE2. For example, the third side insulating layer SL3 may cover the entirety of the side surface of the second pixel electrode PE2. In an embodiment, the third side insulating layer SL3 may cover at least a portion of the fourth protecting insulating layer PL4. For example, the third side insulating layer SL3 may cover the entirety of the fourth protecting insulating layer PLA. In an embodiment, the third side insulating layer SL3 may cover at least a portion of the third dummy layer DP3. For example, the third side insulating layer SL3 may cover the entirety of the third dummy layer DP3.

For example, each of the first side insulating layer SL1, the second side insulating layer SL2, and the third side insulating layer SL3 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The light-emitting layer EML may be disposed on the first pixel electrode PE1 and the second pixel electrode PE2. The light-emitting layer EML may cover at least a portion of each of the first side insulating layer SL1, the second side insulating layer SL2, and the third side insulating layer SL3. In an embodiment, the light-emitting layer EML may be continuously disposed over the first pixel area PX1 and the second pixel area PX2. However, this disclosure is not limited thereto, and in another embodiment, the light-emitting layer EML may be divided into a first light-emitting layer disposed in the first pixel area PX1 and a second light-emitting layer disposed in the second pixel area PX2.

The fourth dummy layer DP4 may be disposed on the second side insulating layer SL2. The fourth dummy layer DP4 may at least partially overlap the second dummy layer DP2 in a plan view. That is, the fourth dummy layer DP4 may be disposed between the first pixel area PX1 and the second pixel area PX2. The fourth dummy layer DP4 and the light-emitting layer EML may be formed through same process. In an embodiment, the fourth dummy layer DP4 may be omitted.

The common electrode CE may be disposed on the light-emitting layer EML. The common electrode CE may include a metal, an alloy, a metal nitride, a conductive metal oxide, a transparent conductive material, and/or the like. These materials may be used alone or in combination with each other. The common electrode CE may operate as a cathode. For example, a portion of the common electrode CE disposed in the first pixel area PX1 may operate as a cathode of the first light emitting element, and a portion of the common electrode CE disposed in the second pixel area PX2 may operate as a cathode of the second light emitting element.

The encapsulation layer TFE may be disposed on the common electrode CE, the first side insulating layer SL1, and the third side insulating layer SL3. The encapsulation layer TFE may include at least one inorganic encapsulation layer and at least one organic encapsulation layer. For example, the inorganic encapsulation layer and the organic encapsulation layer may be alternately stacked. For example, the inorganic encapsulation layer may include silicon oxide, silicon nitride, silicon oxynitride, or the like. These materials may be used alone or in combination with each other. The organic encapsulation layer may include a cured polymer such as polyacrylate.

FIG. 3 is an enlarged cross-sectional view of the area A of FIG. 2.

Referring to FIGS. 2 and 3, the first bridge electrode BR1 may include an upper surface BR1-US and a lower surface BR1-LS in a cross-sectional view. The upper surface BR1-US of the first bridge electrode BR1 may be a surface in contact with the second bridge electrode BR2. The lower surface BR1-LS of the first bridge electrode BR1 may be a surface opposite to the upper surface BR1-US of the first bridge electrode BR1. For example, the lower surface BR1-LS of the first bridge electrode BR1 may be a surface in contact with the first connecting electrode CN1.

As described above, the first bridge electrode BR1 may have a trapezoidal shape in a cross-sectional view. For example, a width W1 of the upper surface BR1-US of the first bridge electrode BR1 in the first direction DR1 may be less than a width W2 of the lower surface BR1-LS of the first bridge electrode BR1 in the first direction DR1. However, this disclosure is not limited thereto, and in another embodiment, the first bridge electrode BR1 may have various shapes such as an inverted trapezoid shape, a square shape, and the like in a cross-sectional view.

In an embodiment, a width W3 of the second bridge electrode BR2 in the first direction DR1 may be greater than a width of the first bridge electrode BR1 in the first direction DR1. In an embodiment, a width W3 of the second bridge electrode BR2 in the first direction DR1 may be greater than the width W2 of the lower surface BR1-LS of the first bridge electrode BR1 in the first direction DR1. However, this disclosure is not limited thereto, and in another embodiment, the width W3 of the second bridge electrode BR2 in the first direction DR1 and the width W2 of the lower surface BR1-LS of the first bridge electrode BR1 in the first direction DR1 may be substantially same.

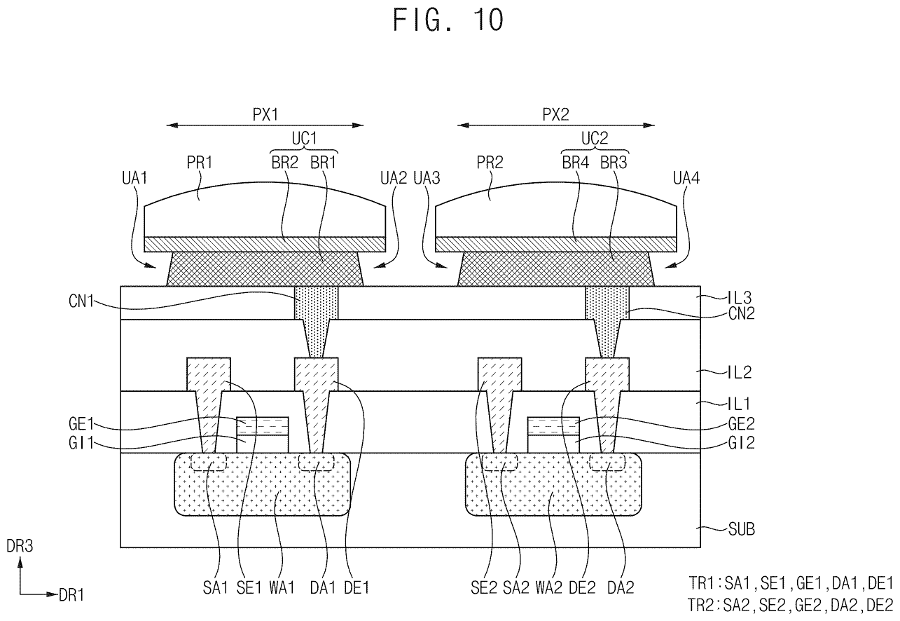

As described above, the width W1 of the upper surface BR1-US of the first bridge electrode BR1 in the first direction DR1 may be smaller than the width W2 of the lower surface BR1-LS of the first bridge electrode BR1 in the first direction DR1, and the width W2 of the lower surface BR1-LS of the first bridge electrode BR1 in the first direction DR1 may be smaller than the width W3 of the second bridge electrode BR2 in the first direction DR1. Accordingly, the first undercut structure UC1 may be defined (or formed). The first undercut structure UC1 may be a structure including the first bridge electrode BR1 and the second bridge electrode BR2. As the first undercut structure UC1 is disposed on the third insulating layer IL3, a first undercut area (e.g., a first undercut area UA1 of FIG. 10) and a second undercut area (e.g., a second undercut area UA2 of FIG. 10) may be defined on the third insulating layer IL3. Each of the first undercut area and the second undercut area may be an area from which a portion of the first bridge electrode BR1 is removed under the second bridge electrode BR2. That is, each of the first undercut area and the second undercut area may be an area in which a portion of the first bridge electrode BR1 and a portion of the second bridge electrode BR2 are not in contact with each other and are spaced apart from each other.

As the first undercut structure UC1 is disposed on the third insulating layer IL3, and the first undercut area and the second undercut area are defined, an etching process for forming (or patterning) the first pixel electrode PE1 may be omitted. That is, forming of a first pixel electrode of a display device according to a comparative example may include forming a preliminary pixel electrode and removing a portion of the preliminary pixel electrode that does not overlap the first pixel area in a plan view through an etching process using a mask. On the other hand, forming of the first pixel electrode PE1 of the display device DD according to an embodiment may only include applying a preliminary pixel electrode on the first undercut structure UC1, and an etching process using the mask may be omitted. Therefore, a mask for forming (or patterning) the first pixel electrode PE1 may not be separately required.

In addition, the third bridge electrode BR3 may include an upper surface BR3-US and a lower surface BR3-LS in a cross-sectional view. The upper surface BR3-US of the third bridge electrode BR3 may be a surface in contact with the fourth bridge electrode BR4. The lower surface BR3-LS of the third bridge electrode BR3 may be a surface opposite to the upper surface BR3-US of the third bridge electrode BR3. For example, the lower surface BR3-LS of the third bridge electrode BR3 may be a surface in contact with the second connecting electrode CN2.

As described above, the third bridge electrode BR3 may have a trapezoidal shape in a cross-sectional view. For example, a width W4 of the upper surface BR3-US of the third bridge electrode BR3 in the first direction DR1 may be less than the width W5 of the lower surface BR3-LS of the third bridge electrode BR3 in the first direction DR1. However, this disclosure is not limited thereto, and in another embodiment, the third bridge electrode BR3 may have various shapes such as an inverted trapezoid shape, a quadrangular shape, and the like in a cross-sectional view.

In an embodiment, a width W6 of the fourth bridge electrode BR4 in the first direction DR1 may be greater than a width of the third bridge electrode BR3 in the first direction DR1. In an embodiment, the width W6 of the fourth bridge electrode BR4 in the first direction DR1 may be greater than the width W5 of the lower surface BR3-LS of the third bridge electrode BR3 in the first direction DR1. However, this disclosure is not limited thereto, and in another embodiment, the width W6 of the fourth bridge electrode BR4 in the first direction DR1 and the width W5 of the lower surface BR3-LS of the third bridge electrode BR3 in the first direction DR1 may be substantially same.

As described above, the width W4 of the upper surface BR3-US of the third bridge electrode BR3 in the first direction DR1 may be smaller than the width W5 of the lower surface BR3-LS of the third bridge electrode BR3 in the first direction DR1, and the width W5 of the lower surface BR3-LS of the third bridge electrode BR3 in the first direction DR1 may be smaller than the width W6 of the fourth bridge electrode BR4. Accordingly, the second undercut structure UC2 may be defined (or formed). The second undercut structure UC2 may be a structure including the third bridge electrode BR3 and the fourth bridge electrode BR4. As the second undercut structure UC2 is disposed on the third insulating layer IL3, a third undercut area (e.g., a third undercut area UA3 of FIG. 10) and a fourth undercut area (e.g., a fourth undercut area UA4 of FIG. 10) may be defined on the third insulating layer IL3. Each of the third undercut area and the fourth undercut area may be an area from which a portion of the third bridge electrode BR3 is removed under the fourth bridge electrode BR4. That is, each of the third undercut area and the fourth undercut area may be an area in which a portion of the third bridge electrode BR3 and a portion of the fourth bridge electrode BR4 are not in contact with each other and are spaced apart from each other.

As the second undercut structure UC2 is disposed on the third insulating layer IL3, and the third undercut area and the fourth undercut area are defined, an etching process for forming (or patterning) the second pixel electrode PE2 may be omitted. That is, forming of a second pixel electrode of a display device according to a comparative example may include forming a preliminary pixel electrode and removing a portion of the preliminary pixel electrode that does not overlap the second pixel area in a plan view through an etching process using a mask. On the other hand, forming of the second pixel electrode PE2 of the display device DD according to an embodiment may only include applying a preliminary pixel electrode on the second undercut structure UC2, and an etching process using the mask may be omitted. Therefore, a mask for forming (or patterning) the second pixel electrode PE2 may not be separately required.

In an embodiment, the light-emitting layer EML may include a 1-1 functional layer E1-1, a 1-2 functional layer E1-2, an organic layer E2, and a second functional layer E3. The 1-1 functional layer E1-1 may be disposed on the first pixel electrode PE1. That is, the 1-1 functional layer E1-1 may be disposed in the first pixel area PX1. For example, the 1-1 functional layer E1-1 may include a hole injection layer, a hole transport layer, and/or the like. The 1-2 functional layer E1-2 may be disposed on the second pixel electrode PE2. That is, the 1-2 functional layer E1-2 may be disposed in the second pixel area PX2. For example, the 1-2 functional layer E1-2 may include a hole injection layer, a hole transport layer, and/or the like.

In an embodiment, the 1-1 functional layer E1-1 and the 1-2 functional layer E1-2 may be separated (or disconnected) from each other. For example, the 1-1 functional layer E1-1 and the 1-2 functional layer E1-2 may be separated (or disconnected) from each other by the second side insulating layer SL2. That is, the 1-1 functional layer E1-1 and the 1-2 functional layer E1-2 may be spaced apart from each other by the second side insulating layer SL2. For example, the 1-1 functional layer E1-1 may be spaced apart from the second pixel area PX2 in a plan view, and the 1-2 functional layer E1-2 may be spaced apart from the first pixel area PX1 in a plan view. As the 1-1 functional layer E1-1 and the 1-2 functional layer E1-2 are separated (or disconnected) from each other through the second side insulating layer SL2, a current may be prevented from flowing into an adjacent pixel area. For example, as the 1-1 functional layer E1-1 and the 1-2 functional layer E1-2 are separated (or disconnected) from each other through the second side insulating layer SL2, a current may be prevented flowing from the first pixel area PX1 to the second pixel area PX2, or a current may be prevented from flowing from the second pixel area PX2 to the first pixel area PX1.

However, this disclosure is not limited thereto, and in another embodiment, only a portion of the 1-1 functional layer E1-1 may be separated (or disconnected) from a portion of the 1-2 functional layer E1-2. For example, only the hole injection layer of the 1-1 functional layer E1-1 may be separated (or disconnected) from the hole injection layer of the 1-2 functional layer E1-2.

In addition, as described above, the first side insulating layer SL1 may cover at least a portion of each of the upper surface of the first pixel electrode PE1 and the side surface of the first pixel electrode PE1. In addition, the second side insulating layer SL2 may cover at least a portion of each of the upper surface of the first pixel electrode PE1 and the side surface of the first pixel electrode PE1. Accordingly, leakage current may be prevented from flowing between the first pixel electrode PE1 and the common electrode CE. For example, a strong electric field may be formed at a corner portion of the first pixel electrode PE1, which is a portion where the upper surface of the first pixel electrode PE1 and the side surface of the first pixel electrode PE1 are in contact with each other, and thus, leakage current may flow between the first pixel electrode PE1 and the common electrode CE. According to an embodiment of the disclosure, as the first side insulating layer SL1 and the second side insulating layer SL2 cover the corner portion of the first pixel electrode PE1, leakage current may be prevented from flowing between the first pixel electrode PE1 and the common electrode CE.

In addition, the second side insulating layer SL2 may cover at least a portion of each of the upper surface of the second pixel electrode PE2 and the side surface of the second pixel electrode PE2. In addition, the third side insulating layer SL3 may cover at least a portion of each of the upper surface of the second pixel electrode PE2 and the side surface of the second pixel electrode PE2. Accordingly, leakage current may be prevented from flowing between the second pixel electrode PE2 and the common electrode CE. For example, a strong electric field may be formed at a corner portion of the second pixel electrode PE2, which is a portion where the upper surface of the second pixel electrode PE2 and the side surface of the second pixel electrode PE2 are in contact with each other, and thus, leakage current may flow between the second pixel electrode PE2 and the common electrode CE. According to an embodiment of the disclosure, as the second side insulating layer SL2 and the third side insulating layer SL3 cover the corner portion of the second pixel electrode PE2, leakage current may be prevented from flowing between the second pixel electrode PE2 and the common electrode CE.

The organic layer E2 may be disposed on the 1-1 functional layer E1-1 and the 1-2 functional layer E1-2. In an embodiment, the organic layer E2 may be continuously disposed over the first pixel area PX1 and the second pixel area PX2. For example, the organic layer E2 may include a light-emitting material.

The second functional layer E3 may be disposed on the organic layer E2. In an embodiment, the second functional layer E3 may be continuously disposed over the first pixel area PX1 and the second pixel area PX2. For example, the second functional layer E3 may include an electron transport layer, an electron injection layer, and/or the like.

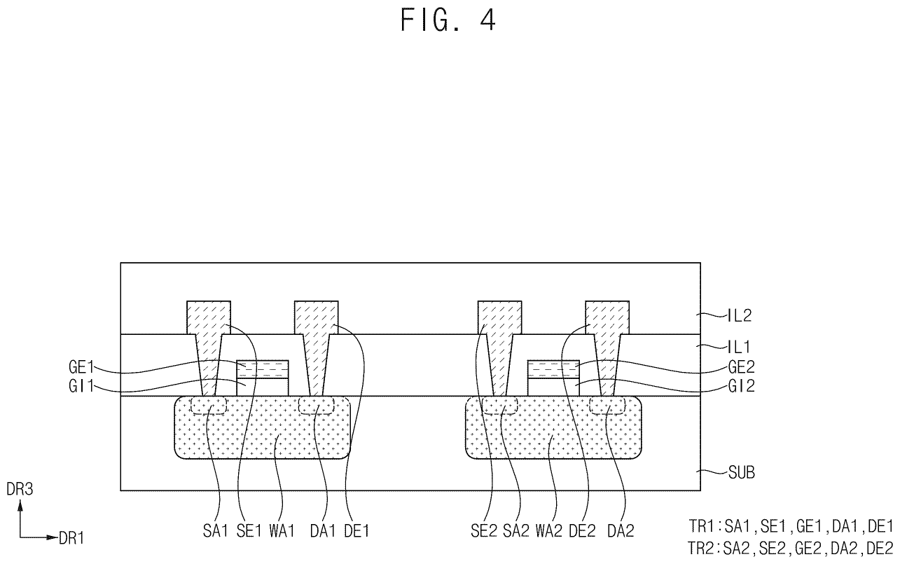

FIGS. 4, 5, 6, 7, 8, 9, 10, 11, 12, 13, 14, 15, 16, 17, and 18 are cross-sectional views illustrating a method of manufacturing the display device of FIG. 2.

Referring to FIG. 4, the substrate SUB forming a base of the display device (e.g., the display device DD of FIG. 2) may be formed. In an embodiment, the substrate SUB may be a silicon substrate. For example, the substrate SUB may be a p-type silicon substrate or an n-type silicon substrate. In this case, p may mean a hole, and n may mean electron. The substrate SUB may include a first well area WA1 and a second well area WA2. The first well area WA1 may be a p-well or an n-well depending on a type of the first transistor TR1 and a type of the substrate SUB. In addition, the second well area WA2 may be a p-well or an n-well depending on a type of the second transistor TR2 and a type of the substrate SUB.

The substrate SUB may include the first contact area SA1 and the second contact area DA1. For example, the first contact area SA1 and the second contact area DA1 may be an n-source area and an n-drain area, respectively. However, this disclosure is not limited thereto, and the first contact area SA1 and the second contact area DA1 may be a p-source area and a p-drain area, respectively in another embodiment.

The substrate SUB may further include the third contact area SA2 and the fourth contact area DA2. For example, the third contact area SA2 and the fourth contact area DA2 may be an n-source area and an n-drain area, respectively. However, this disclosure is not limited thereto, and the third contact area SA2 and the fourth contact area DA2 may be a p-source area and a p-drain area, respectively in another embodiment.

In another embodiment, the substrate SUB may be formed of a transparent resin substrate. Example of the transparent resin substrate may include a polyimide substrate. In this case, the polyimide substrate may include a first organic layer, a first barrier layer, a second organic layer, and/or the like. Optionally, the substrate SUB may include a quartz substrate (e.g. a synthetic quartz substrate, a fluorine-doped quartz substrate), a calcium fluoride substrate, a soda lime glass substrate, a non-alkali glass substrate, or the like. These materials may be used alone or in combination with each other. In this case, the display device DD may include a first active pattern disposed in at least a portion of the first pixel area PX1 and a second active pattern disposed in at least a portion of the second pixel area PX2 on the substrate SUB.

The first gate insulating layer GI1 and the second gate insulating layer GI2 may be formed on the substrate SUB. The first gate insulating layer GI1 may be formed to at least partially overlap the first well area WA1 in a plan view. In addition, the second gate insulating layer GI2 may be formed to at least partially overlap the second well area WA2 in a plan view.

Each of the first gate insulating layer GI1 and the second gate insulating layer GI2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first gate electrode GE1 may be formed on the first gate insulating layer GI1. For example, the first gate electrode GE1 may be formed to overlap the first gate insulating layer GI1 in a plan view. The second gate electrode GE2 may be formed on the second gate insulating layer GI2. For example, the second gate electrode GE2 may be formed to overlap the second gate insulating layer GI2 in a plan view.

Each of the first gate electrode GE1 and the second gate electrode GE2 may include a metal, an alloy, a metal nitride, a conductive metal oxide, a transparent conductive material, or the like.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

The first insulating layer IL1 may be formed on the substrate SUB. The first insulating layer IL1 may be formed to sufficiently cover the first gate electrode GEL and the second gate electrode GE2.

The first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first contact electrode SE1, the second contact electrode DE1, the third contact electrode SE2 and the fourth contact electrode DE2 may be formed on the first insulating layer IL1. For example, after the first contact hole overlapping the first contact area SA1 in a plan view is formed in the first insulating layer IL1, the first contact electrode SE1 may be formed to fill the first contact hole. In addition, after the second contact hole overlapping the second contact area DA1 in a plan view is formed in the first insulating layer IL1, the second contact electrode DE1 may be formed to fill the second contact hole. In addition, after the third contact hole overlapping the third contact area SA2 in a plan view is formed in the first insulating layer IL1, the third contact electrode SE2 may be formed to fill the third contact hole. In addition, after the fourth contact hole overlapping the fourth contact area DA2 in a plan view is formed in the first insulating layer IL1, the fourth contact electrode DE2 may be formed to fill the fourth contact hole.

Each of the first contact electrode SE1, the second contact electrode DE1, the third contact electrode SE2, and the fourth contact electrode DE2 may include a metal, an alloy metal nitride, a conductive metal oxide, a transparent conductive material, or the like. These may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

That is, the first transistor TR1 and the second transistor TR2 may be formed on the substrate SUB. The second transistor TR2 may be formed to be spaced apart from the first transistor TR1 in a plan view. For example, the first transistor TR1 may be formed in at least a portion of the first pixel area PX1, and the second transistor TR2 may be formed in at least a portion of the second pixel area PX2.

The second insulating layer IL2 may be formed on the first insulating layer IL1. The second insulating layer IL2 may be formed to sufficiently cover the first contact electrode SE1, the second contact electrode DE1, the third contact electrode SE2 and the fourth contact electrode DE2.

The second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

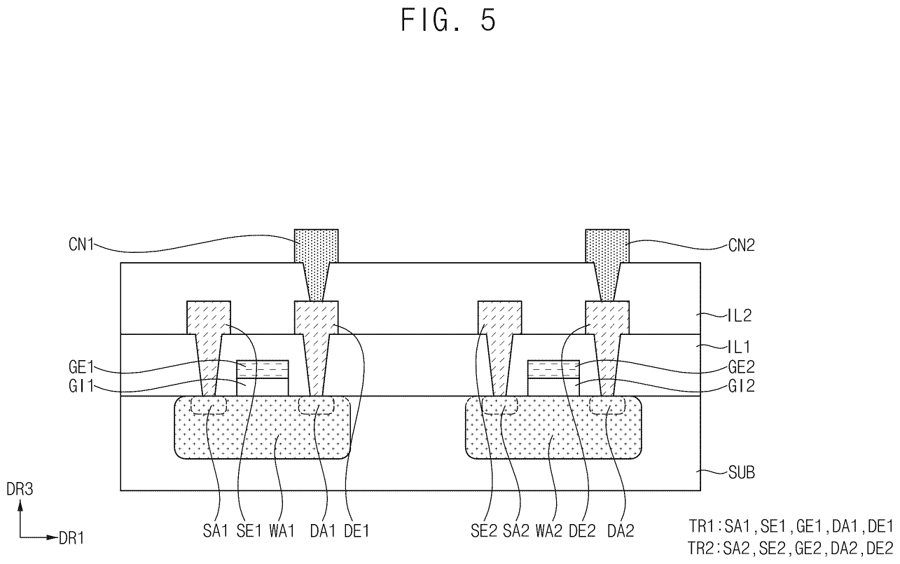

Referring to FIG. 5, the first connecting electrode CN1 and a second connecting electrode CN2 may be formed on the second insulating layer IL2. For example, the fifth contact hole overlapping the second contact electrode DE1 in a plan view may be formed in the second insulating layer IL2, and the first connecting electrode CN1 may be formed to fill the fifth contact hole. In addition, the sixth contact hole overlapping the fourth contact electrode DE2 in a plan view may be formed in the second insulating layer IL2, and the second connecting electrode CN2 may be formed to fill the sixth contact hole.

Each of the first connecting electrode CN1 and the second connecting electrode CN2 may include a metal, an alloy metal nitride, a conductive metal oxide, a transparent conductive material, or the like. These may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

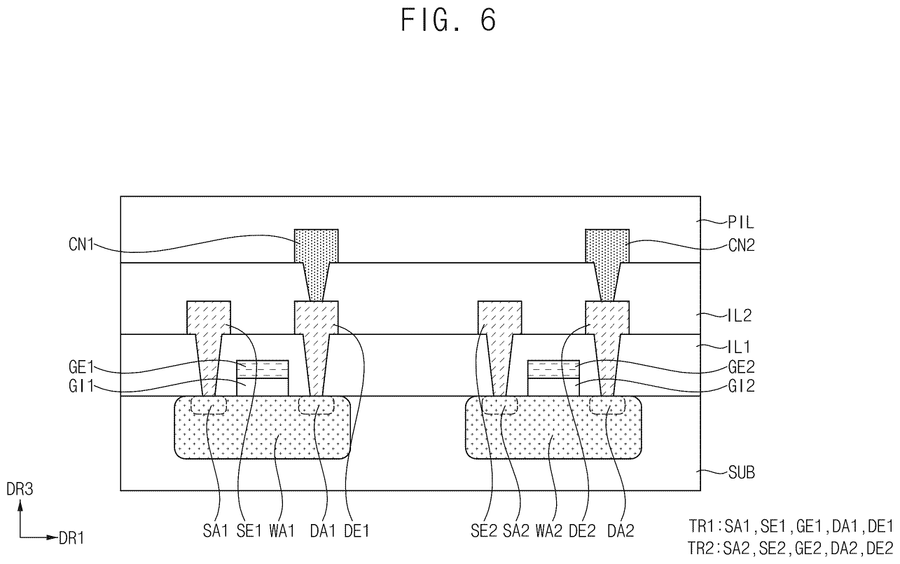

Referring to FIG. 6, a preliminary insulating layer PIL may be formed on the second insulating layer IL2. The preliminary insulating layer PIL may be formed to sufficiently cover the first connecting electrode CN1 and the second connecting electrode CN2.

In an embodiment, the preliminary insulating layer PIL may include an organic material. For example, the preliminary insulating layer PIL may include phenolic resin, acrylic resin, polyimide resin, polyamide resin, siloxane resin, epoxy resin, or the like. These materials may be used alone or in combination with each other. However, this disclosure is not limited thereto, and in another embodiment, the preliminary insulating layer PIL may include inorganic materials such as silicon oxide and silicon nitride. These materials may be used alone or in combination with each other.

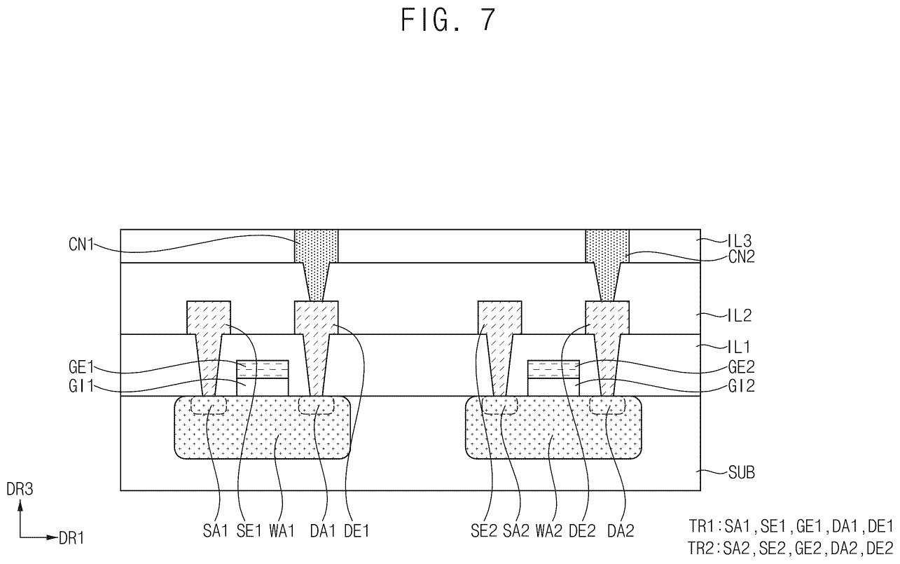

Referring to FIGS. 6 and 7, a portion of the preliminary insulating layer PIL may be removed to form the third insulating layer IL3. For example, the portion of the preliminary insulating layer PIL may be removed such that an upper surface of the third insulating layer IL3 is positioned at substantially the same level as an upper surface of each of the first connecting electrode CN1 and the second connecting electrode CN2. For example, the portion of the preliminary insulating layer PIL may be removed by a chemical mechanical polishing (“CMP”) process.

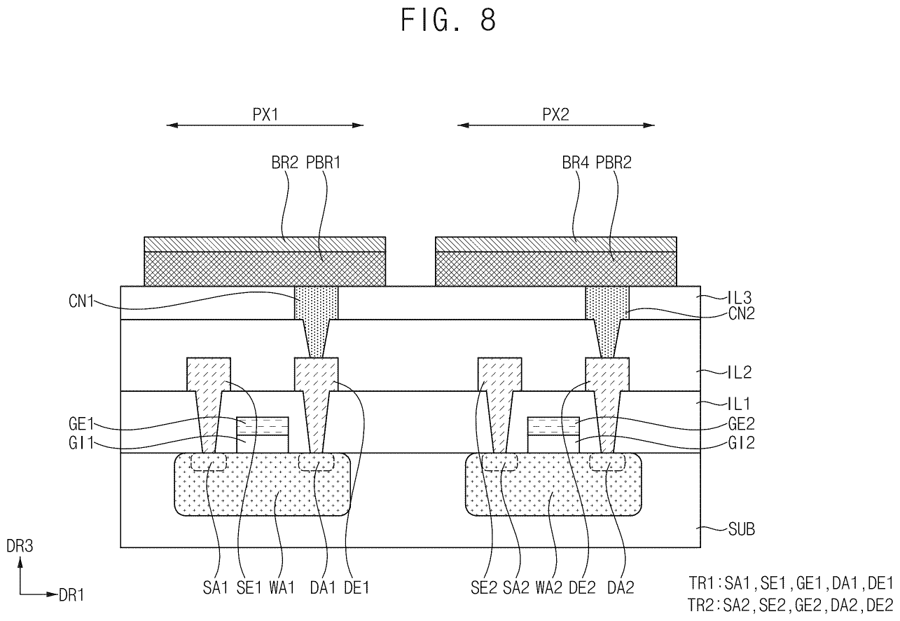

Referring to FIG. 8, a first preliminary bridge electrode PBR1 and a second preliminary bridge electrode PBR2 may be formed on the third insulating layer IL3. The first preliminary bridge electrode PBR1 may be formed on the first transistor TR1. The first formed in the first pixel area PX1. The preliminary bridge electrode PBR1 may be second preliminary bridge electrode PBR2 may be formed on the second transistor TR2. The second preliminary bridge electrode PBR2 may be formed in the second pixel area PX2.

For example, each of the first preliminary bridge electrode PBR1 and the second preliminary bridge electrode PBR2 may include a metal, an alloy metal nitride, a conductive metal oxide, a transparent conductive material, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

The second bridge electrode BR2 may be formed on the first preliminary bridge electrode PBR1. The second bridge electrode BR2 may be formed in the first pixel area PX1. In addition, the fourth bridge electrode BR4 may be formed on the second preliminary bridge electrode PBR2. The fourth bridge electrode BR4 may be formed in the second pixel area PX2.

Each of the second bridge electrode BR2 and the fourth bridge electrode BR4 may include a metal, an alloy metal nitride, a conductive metal oxide, a transparent conductive material, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include Indium tin oxide, indium zinc oxide, or the like. These materials may be used alone or in combination with each other. In addition, examples of the metal nitride may include aluminum nitride (“AlNₓ”), tungsten nitride (“WNₓ”), chromium nitride (“CrNₓ”), or the like. These materials may be used alone or in combination with each other.

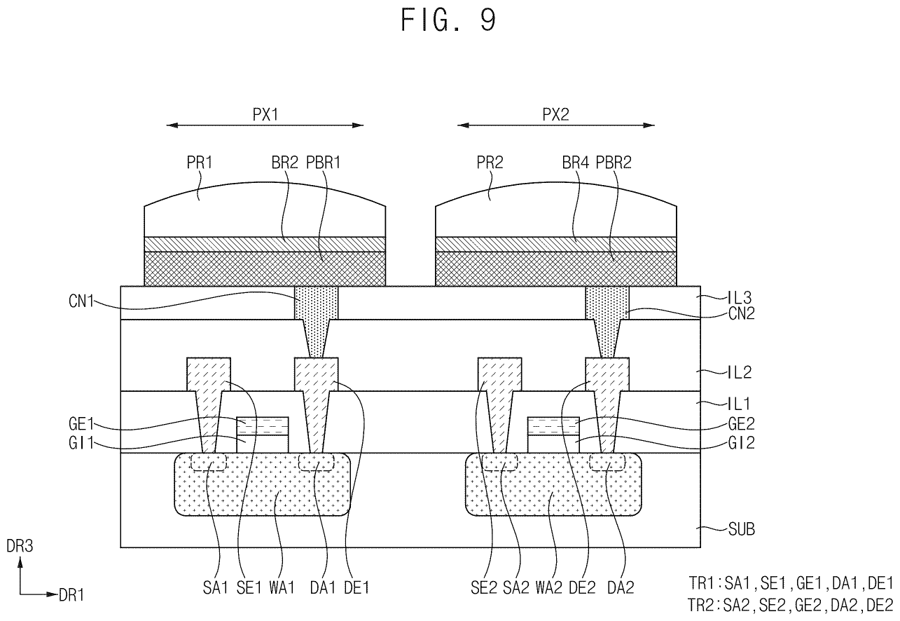

Referring to FIG. 9, a first photoresist layer PR1 may be formed on the second bridge electrode BR2. The first photoresist layer PR1 may be formed in the first pixel area PX1. In addition, a second photoresist layer PR2 may be formed on the fourth bridge electrode BR4. The second photoresist layer PR2 may be formed in the second pixel area PX2. For example, each of the first photoresist layer PR1 and the second photoresist layer PR2 may include an organic material.

Referring to FIGS. 9 and 10, a portion of the first preliminary bridge electrode PBR1 may be removed to form the first bridge electrode BR1. For example, the portion of the first preliminary bridge electrode PBR1 may be removed by a wet etching process to form the first bridge electrode BR1. In this case, the first photoresist layer PR1 may be used as a mask for wet etching. Accordingly, the first undercut structure UC1 including the first bridge electrode BR1 and the second bridge electrode BR2 may be formed on the third insulating layer IL3. In addition, the first undercut area UA1 and the second undercut area UA2 may be formed on the third insulating layer IL3.

In addition, a portion of the second preliminary bridge electrode PBR2 may be removed to form the third bridge electrode BR3. For example, the portion of the second preliminary bridge electrode PBR2 may be removed by a wet etching process to form the third bridge electrode BR3. In this case, the second photoresist layer PR2 may be used as a mask for wet etching. Accordingly, the second undercut structure UC2 including the third bridge electrode BR3 and the fourth bridge electrode BR4 may be formed on the third insulating layer IL3. In addition, the third undercut area UA3 and the fourth undercut area UA4 may be formed on the third insulating layer IL3.

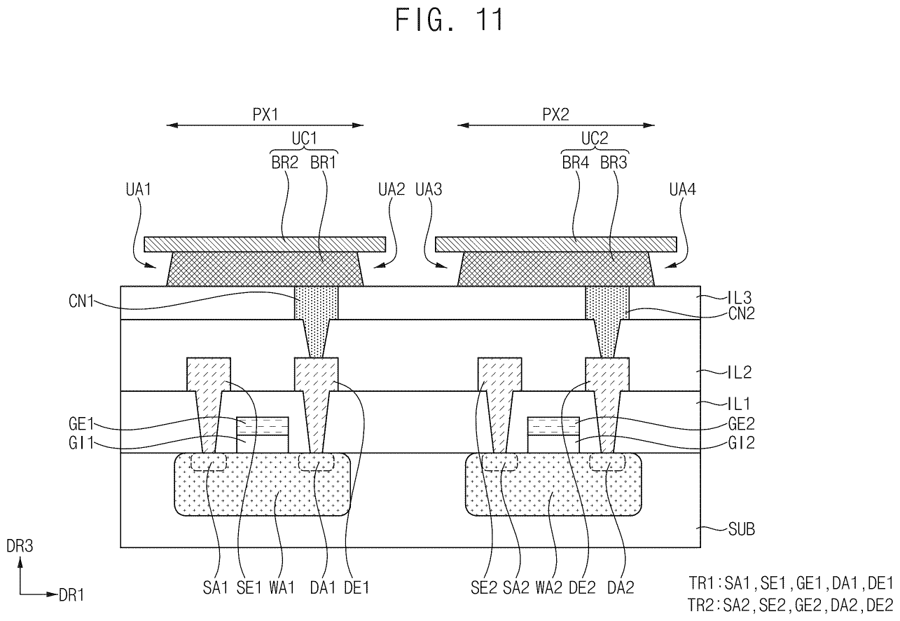

Referring to FIGS. 10 and 11, the first photoresist layer PR1 and the second photoresist layer PR2 may be removed. For example, each of the first photoresist layer PR1 and the second photoresist layer PR2 may be removed through a strip process.

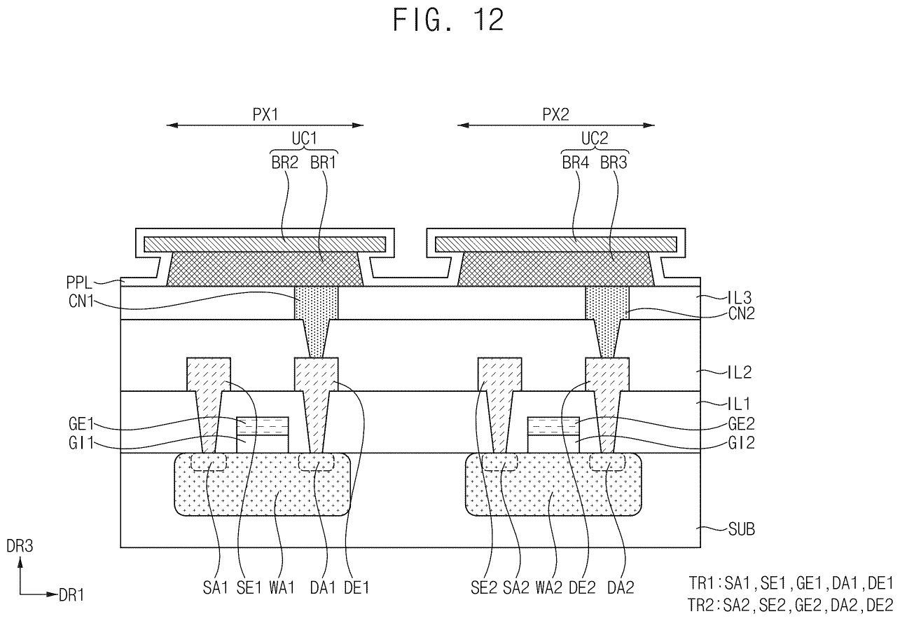

Referring to FIG. 12, a preliminary protecting insulating layer PPL may be formed on the third insulating layer IL3. The preliminary protecting insulating layer PPL may be formed to cover the first undercut structure UC1 and the second undercut structure UC2. For example, the preliminary protecting insulating layer PPL may be formed to cover the first bridge electrode BR1, the second bridge electrode BR2, the third bridge electrode BR3, and the fourth bridge electrode BR4. For example, the preliminary protecting insulating layer PPL may be continuously formed over the first pixel area PX1 and the second pixel area PX2.

For example, preliminary protecting insulating layer PPL may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

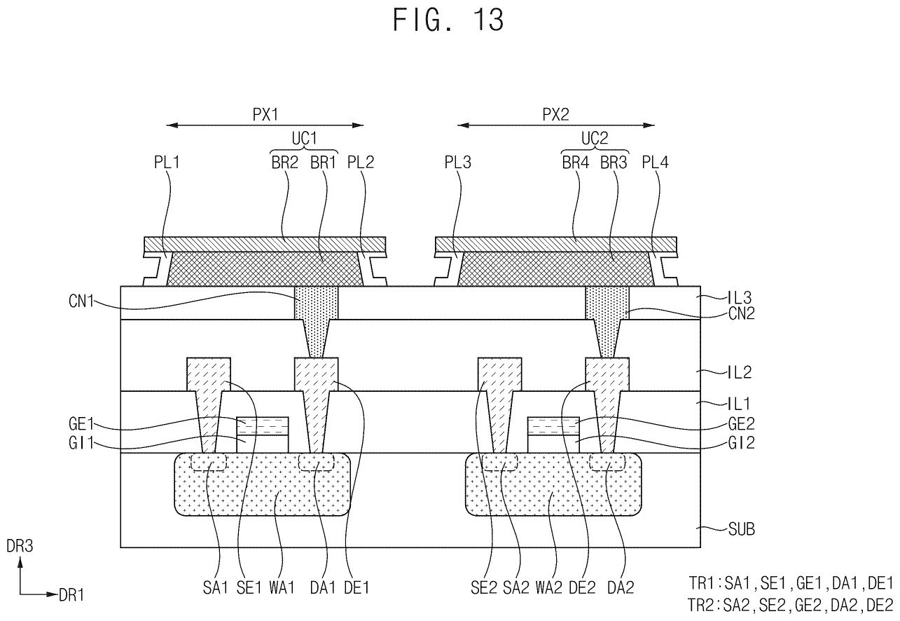

Referring to FIGS. 12 and 13, a portion of the preliminary protecting insulating layer PPL may be removed to form the first protecting insulating layer PL1, the second protecting insulating layer PL2, the third protecting insulating layer PL3, and the fourth protecting insulating layer PL4. In an embodiment, the portion of the preliminary protecting insulating layer PPL may be removed by an anisotropic dry etching process without a mask. For example, the portion of the preliminary protecting insulating layer PPL may be removed by an anisotropic dry etching process in a vertical direction (i.e., third direction DR3). In this case, a portion of the preliminary protecting insulating layer PPL covering a side surface of the first bridge electrode BR1 may remain to form the first protecting insulating layer PL1 and the second protecting insulating layer PL2. In addition, a portion of the preliminary protecting insulating layer PPL covering a side surface of the second bridge electrode BR2 may remain to form the third protecting insulating layer PL3 and the fourth protecting insulating layer PL4. Accordingly, a separate mask for forming each of the first protecting insulating layer PL1, the second protecting insulating layer PL2, the third protecting insulating layer PL3 and the fourth protecting insulating layer PL4 may not be required.

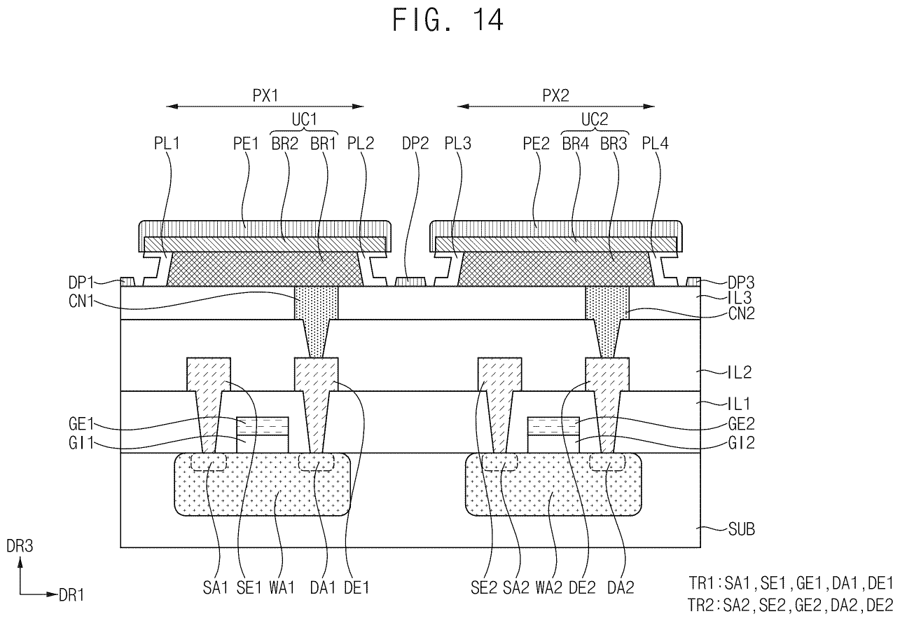

Referring to FIG. 14, the first pixel electrode PE1 may be formed on the second bridge electrode BR2. The first pixel electrode PE1 may be formed in the first pixel area PX1. As described above, the forming of the first pixel electrode PE1 may only include applying the preliminary pixel electrode on the first undercut structure UC1, and the etching process using a mask may be omitted. Therefore, a mask for forming (or patterning) the first pixel electrode PE1 may not be separately required.

In an embodiment, the forming of the first pixel electrode PE1 may include forming a first layer and forming a second layer. For example, the forming of the first layer of the first pixel electrode PE1 may be performed through a thermal evaporation process. In addition, the forming of the second layer of the first pixel electrode PE1 may be performed through a sputtering process. That is, the forming of the first pixel electrode PE1 may include forming a portion of the first pixel electrode PE1 through a thermal deposition method. In this case, the first layer of the first pixel electrode PE1 may include silver (“Ag”), and the second layer of the first pixel electrode PE1 may include indium tin oxide (“ITO”), but this disclosure is not limited thereto.

In another embodiment, the forming of the first pixel electrode PE1 may include forming a first layer, forming a second layer, and forming a third layer. For example, the forming of the first layer of the first pixel electrode PE1 may be performed through a sputtering process. In addition, the forming of the second layer of the first pixel electrode PE1 may be performed through a thermal deposition process. In addition, the forming of the third layer of the first pixel electrode PE1 may be formed through a sputtering process. In this case, the first layer of the first pixel electrode PE1 may include indium tin oxide (“ITO”), the second layer of the first pixel electrode PE1 may include silver (“Ag”), and the third layer of the first pixel electrode PE1 may include indium tin oxide (“ITO”), but this disclosure is not limited thereto.

The first dummy layer DP1 may be formed on the third insulating layer IL3. For example, the first dummy layer DP1 may be spaced apart from the first pixel area PX1 in a direction opposite to the first direction DR1. The first dummy layer DP1 may be formed as the first pixel electrode PE1 is separated by the first undercut structure UC1. That is, the first dummy layer DP1 and the first pixel electrode PE1 may be formed through the same process. In an embodiment, the first dummy layer DP1 may be omitted.

The second dummy layer DP2 may be formed on the third insulating layer IL3. For example, the second dummy layer DP2 may be formed between the first pixel area PX1 and the second pixel area PX2. The second dummy layer DP2 may be formed as the first pixel electrode PE1 and/or the second pixel electrode PE2 are separated by the first undercut structure UC1 and/or the second undercut structure UC2. That is, the second dummy layer DP2 may be formed through same process as the first pixel electrode PE1 and/or the second pixel electrode PE2. In an embodiment, the second dummy layer DP2 may be omitted.

The third dummy layer DP3 may be formed on the third insulating layer IL3. For example, the third dummy layer DP3 may be spaced apart from the second pixel area PX2 in the first direction DR1. The third dummy layer DP3 may be formed as the second pixel electrode PE2 is separated by the second undercut structure UC2. That is, the third dummy layer DP3 and the second pixel electrode PE2 may be formed through same process. In an embodiment, the third dummy layer DP3 may be omitted.

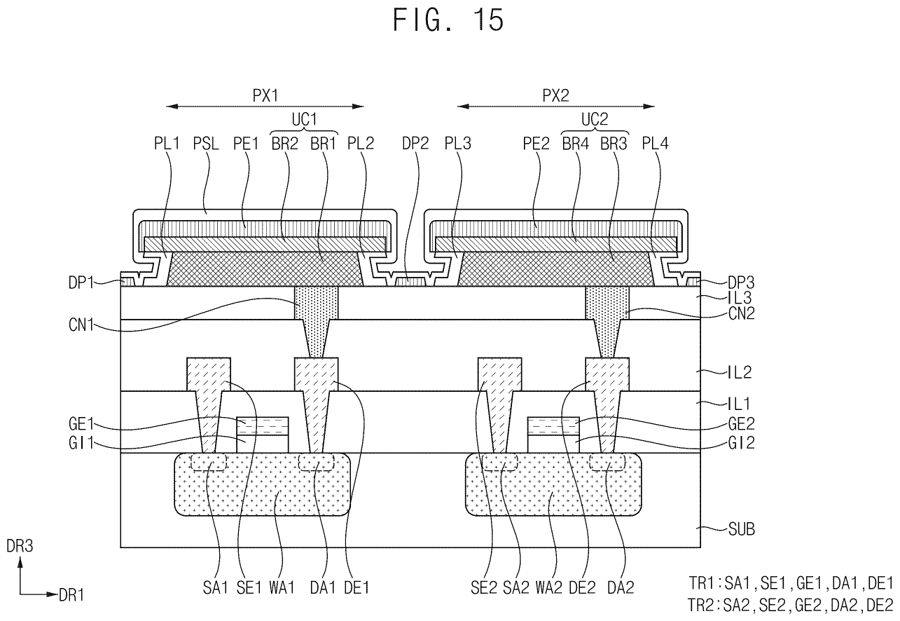

Referring to FIG. 15, a preliminary side insulating layer PSL may be formed on the third insulating layer IL3. For example, the preliminary side insulating layer PSL may be formed to cover the first pixel electrode PE1, the second pixel electrode PE2, the first protecting insulating layer PL1, the second protecting insulating layer PL2, the third protecting insulating layer PL3, the fourth protecting insulating layer PL4, the first dummy layer DP1, the second dummy layer DP2, and the third dummy layer DP3.

In an embodiment, the preliminary side insulating layer PSL may be formed by atomic layer deposition (“ALD”). However, this disclosure is not limited thereto, and in another embodiment, the preliminary side insulating layer PSL may be formed by various processes such as chemical vapor deposition (“CVD”), physical vapor deposition (“PVD”), and the like.

For example, the preliminary side insulating layer PSL may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

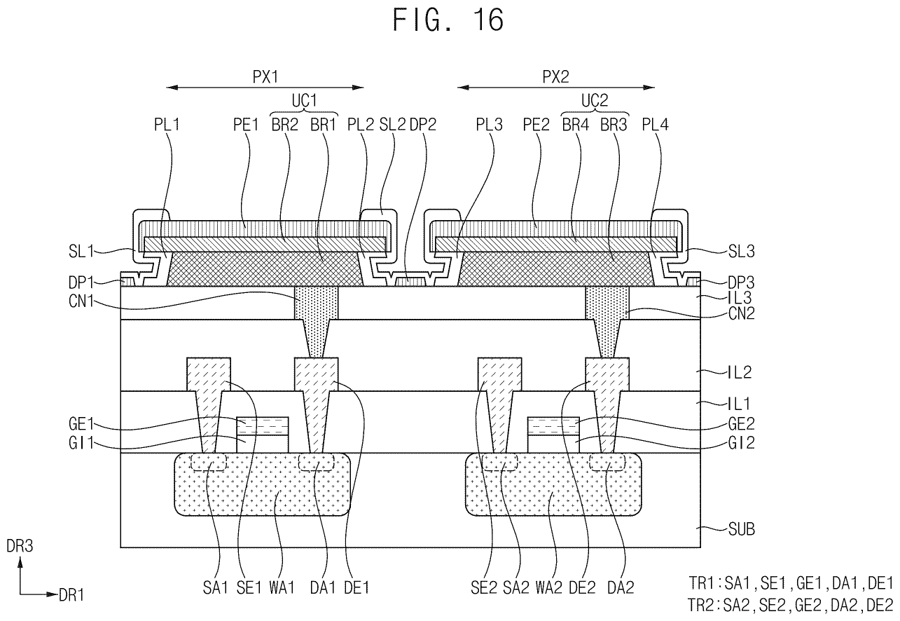

Referring to FIGS. 15 and 16, a portion of the preliminary side insulating layer PSL may be removed to form the first side insulating layer SL1, the second side insulating layer SL2, and the third side insulating layer SL3. For example, a portion of the preliminary side insulating layer PSL overlapping the first pixel area PX1 in a plan view and a portion of the preliminary side insulating layer PSL overlapping the second pixel area PX2 in a plan view are removed to form the first side insulating layer SL1, the second side insulating layer SL2, and the third side insulating layer SL3.

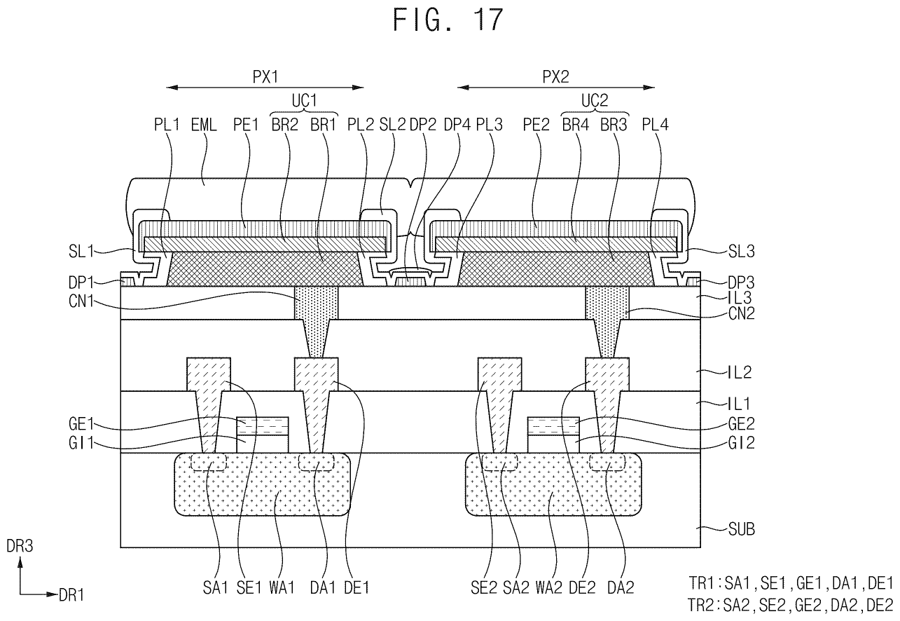

Referring to FIG. 17, the light-emitting layer EML may be formed on the first pixel electrode PE1 and the second pixel electrode PE2. The light-emitting layer EML may be formed to cover at least a portion of each of the first side insulating layer SL1, the second side insulating layer SL2, and the third side insulating layer SL3. In an embodiment, the light-emitting layer EML may be continuously formed over the first pixel area PX1 and the second pixel area PX2. However, this disclosure is not limited thereto, and in another embodiment, the light-emitting layer EML may be formed by being separated into the first light-emitting layer disposed in the first pixel area PX1 and the second light-emitting layer disposed in the second pixel area PX2.

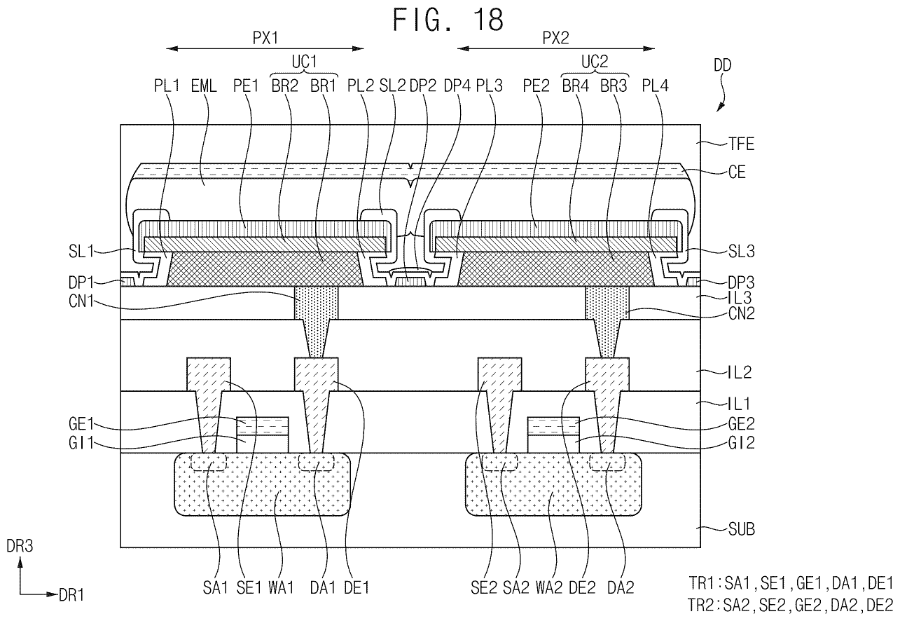

Referring to FIG. 18, the common electrode CE may be formed on the light-emitting layer EML. The common electrode CE may include a metal, an alloy, a metal nitride, a conductive metal oxide, a transparent conductive material, or the like. These materials may be used alone or in combination with each other.

The encapsulation layer TFE may be formed on the common electrode CE, the first side insulating layer SL1, and the third side insulating layer SL3. The encapsulation layer TFE may include at least one inorganic encapsulation layer and at least one organic encapsulation layer. For example, the inorganic encapsulation layer and the organic encapsulation layer may be alternately stacked. For example, the inorganic encapsulation layer may include silicon oxide, silicon nitride, silicon oxynitride, or the like. These materials may be used alone or in combination with each other. The organic encapsulation layer may include a cured polymer such as polyacrylate.

The display device (e.g., the display device DD of FIG. 1) according to embodiments may be applied to various electronic devices. An electronic device according to embodiments may include the above-described display device, and may further include a module or device having other additional functions in addition to the display device.

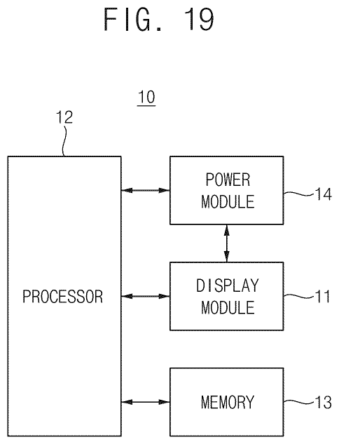

FIG. 19 is a block diagram illustrating an electronic device according to embodiments.

Referring to FIG. 19, an electronic device 10 according to embodiments may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Data information necessary for operation of the processor 12 or the display module 11 may be stored in the memory 15. When the processor 12 executes an application stored in the memory 15, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power required for operation of the electronic device 10.

At least one of components of the electronic device 10 described above may be included in the display device according to the above-described embodiments. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

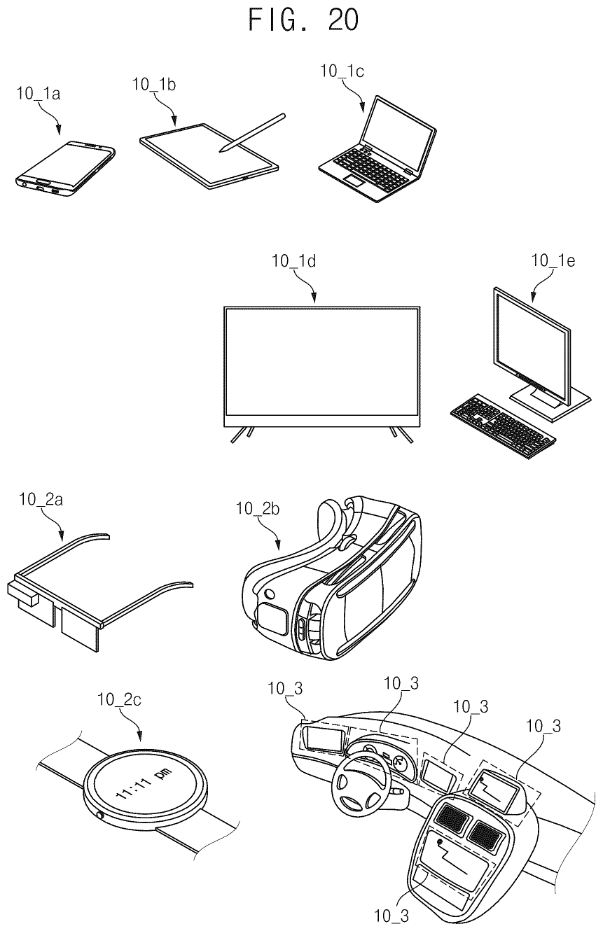

FIG. 20 is a schematic diagram of an electronic device according to various embodiments.

Referring to FIG. 20, various electronic devices to which display devices according to embodiments are applied may include not only electronic devices for image display such as a smartphone 10_1a, a tablet PC 10_1b, a laptop 10_1c, a TV 10_1d, a desk monitor 10_1e, and/or the like, but also wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) disposed on a dashboard, a room mirror display, and/or the like.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate including a first pixel area and a second pixel area spaced apart from the first pixel area in a certain direction;
a first transistor disposed on the substrate;
a first bridge electrode disposed in the first pixel area on the first transistor and electrically connected to the first transistor;
a second bridge electrode disposed on the first bridge electrode, wherein a width of the second bridge electrode in the direction is greater than a width of the first bridge electrode in the direction; and
a first electrode disposed on the second bridge electrode.

2. The display device of claim 1, further comprising:
a second transistor disposed on the substrate and spaced apart from the first transistor in a plan view;
a third bridge electrode disposed in the second pixel area on the second transistor and electrically connected to the second transistor;
a fourth bridge electrode disposed on the third bridge electrode; and
a second electrode disposed on the fourth bridge electrode,
wherein a width of the fourth bridge electrode in the direction is greater than a width of the third bridge electrode in the direction.

3. The display device of claim 2, wherein the first electrode and the second electrode are separated from each other.

4. The display device of claim 1, wherein the first bridge electrode has a trapezoidal shape in a cross-sectional view.

5. The display device of claim 1, further comprising:
a protecting insulating layer covering a side surface of the first bridge electrode.

6. The display device of claim 1, further comprising:
a side insulating layer covering at least a portion of each of an upper surface of the first electrode and a side surface of the first electrode.

7. The display device of claim 6, further comprising:
a light-emitting layer disposed on the first electrode,
wherein the light-emitting layer covers at least a portion of the side insulating layer.

8. The display device of claim 7, wherein the light-emitting layer includes:
a first functional layer disposed on the first electrode and spaced apart from the second pixel area in a plan view;
an organic layer disposed on the first functional layer; and
a second functional layer disposed on the organic layer.

9. The display device of claim 1, wherein the first electrode covers a side surface of the second bridge electrode.

10. The display device of claim 1, wherein a portion of the first bridge electrode and a portion of the second bridge electrode are spaced apart from each other to define an undercut area.

11. The display device of claim 1, wherein the first electrode includes silver (Ag).

12. The display device of claim 11, wherein the first electrode further includes indium tin oxide (ITO).

13. The display device of claim 1, further comprising:
a connecting electrode disposed on the first transistor,
wherein the first transistor and the first bridge electrode are electrically connected through the connecting electrode.

14. A method of manufacturing a display device, the method comprising:
forming a transistor on a substrate;
forming a first preliminary bridge electrode electrically connected to the transistor on the transistor;
forming a second bridge electrode on the first preliminary bridge electrode;
forming a first bridge electrode by removing at least a portion of a side surface of the first preliminary bridge electrode;
forming a protecting insulating layer covering a side surface of the first bridge electrode; and
forming a pixel electrode on the second bridge electrode.

15. The method of claim 14, wherein the forming of the first bridge electrode includes,
forming a photoresist layer on the second bridge electrode; and
removing the at least a portion of the side surface of the first preliminary bridge electrode through an etching process.

16. The method of claim 14, wherein the forming of the protecting insulating layer includes,
forming a preliminary protecting insulating layer covering the first bridge electrode and the second bridge electrode; and
removing at least a portion of the preliminary protecting insulating layer through an anisotropic dry etching process.

17. The method of claim 14, wherein the forming of the pixel electrode includes forming a portion of the pixel electrode through thermal evaporation.

18. The method of claim 17, wherein the portion of the pixel electrode includes silver (Ag).

19. The method of claim 14, further comprising:
forming a side insulating layer covering at least a portion of each of an upper surface of the pixel electrode and a side surface of the pixel electrode.

20. An electronic device comprising:
a substrate including a first pixel area and a second pixel area spaced apart from the first pixel area in a certain direction;
a first transistor disposed on the substrate;
a first bridge electrode disposed in the first pixel area on the first transistor and electrically connected to the first transistor;
a second bridge electrode disposed on the first bridge electrode, wherein a width of the second bridge electrode in the direction is greater than a width of the first bridge electrode in the direction;
a first electrode disposed on the second bridge electrode; and
a memory where data information is stored.
